(19) United States
(12) Patent Application Publication
(10) Pub. No.: US 2012/0069245 A1
(43) Pub. Date: Mar. 22, 2012

(54) Video System Sampling Phase Determination

(75) Inventors: Lakhbir Singh Gandhi, Auburn, WA (US); Mark Champion, Kenmore, WA (US); Joel Sandgathe, Portland, OR (US)

(73) Assignee: MICROVISION, INC., Redmond, WA (US)

(21) Appl. No.: 12/887,748

(22) Filed: Sep. 22, 2010

(51) Int. Cl. H03L 7/00; H03M 1/12

(52) U.S. Cl. 348/537; 348/539; 348/572; 348/E05.019

(57) ABSTRACT

A phase for an analog-to-digital converter sampling clock is determined. The analog-to-digital converter samples a video signal to generate pixel values. Differences of successive pixel values are compared to a threshold. The number of times the threshold is exceeded is counted for multiple phase values to create a phase profile. The threshold may be dynamic.

### FIELD

The present invention relates generally to video display systems, and more specifically to video systems that sample analog video signals.

### BACKGROUND

When sampling analog video signals, determining the proper sampling frequency is not a difficult problem. Determining the proper sampling phase, however, is a difficult problem. If the sampling phase is wrong, the analog video signal may be sampled during pixel transitions rather than when pixels are stable. This may result in blurring of, or otherwise distorted, display images.

### BRIEF DESCRIPTION OF THE DRAWINGS

FIG. 1 shows a video system with a sampling phase determination component in accordance with various embodiments of the present invention;

FIG. 2 shows a video signal and possible sampling clocks with different phases;

FIG. 3 shows a video system with a sampling phase determination component in accordance with various embodiments of the present invention;

FIG. 4 shows a phase profile in accordance with various embodiments of the present invention;

FIG. 5 shows a monochrome video system with a sampling phase determination component in accordance with various embodiments of the present invention;

FIG. 6 shows a color video system with a sampling phase determination component in accordance with various embodiments of the present invention;

FIG. 7 shows a flowchart of a method for generating a phase profile in accordance with various embodiments of the present invention;

FIG. 8 shows a flowchart of a method for dynamically determining a threshold in accordance with various embodiments of the present invention;

FIGS. 9 and 10 show flowcharts of methods for determining a sampling phase in accordance with various embodiments of the present invention;

FIG. 11 shows a color scanning laser projector;

FIG. 12 shows a block diagram of a mobile device in accordance with various embodiments of the present invention;

FIG. 13 shows a mobile device in accordance with various embodiments of the present invention;

FIG. 14 shows a head-up display system in accordance with various embodiments of the invention; and

FIG. 15 shows eyewear in accordance with various embodiments of the invention.

### DESCRIPTION OF EMBODIMENTS

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein in connection with one embodiment may be implemented within other embodiments without departing from the spirit and scope of the invention. In addition, it is to be understood that the location or arrangement of individual elements within each disclosed embodiment may be modified without departing from the scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

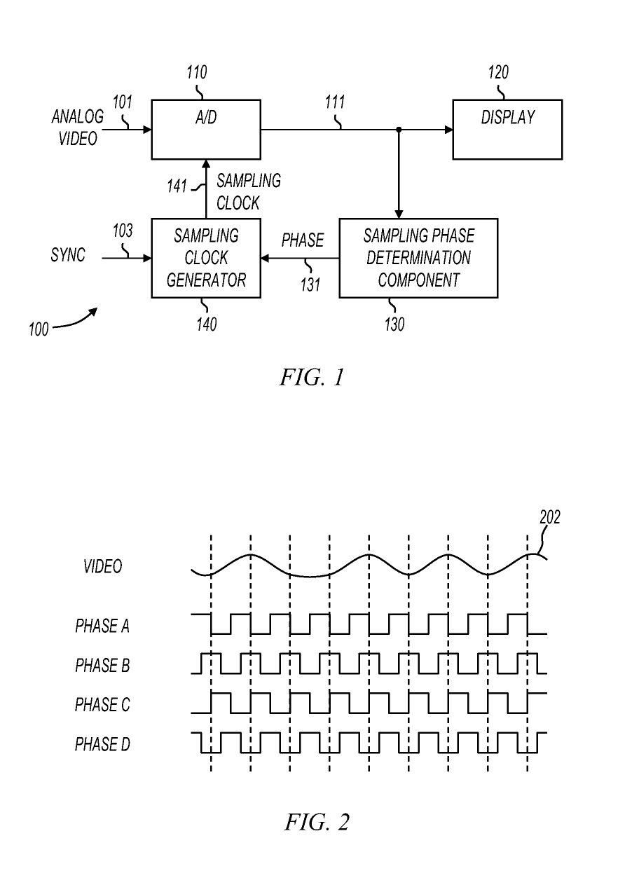

FIG. 1 shows a video system with a sampling phase determination component in accordance with various embodiments of the present invention. System 100 includes analog-to-digital converter (A/D) 110, display 120, sampling clock generator 140, and sampling phase determination component 130.

In operation, A/D 110 receives an analog video signal on node 101 and a sampling clock on node 141. A/D 110 samples the analog video signal at times determined by the phase and frequency of the sampling clock, and generates pixel values on node 111. Node 111 may be any width. For example, node 111 may include eight physical conductors to carry eight bits of video data for each pixel value.

Display 120 receives the pixel values on node 111 and displays a corresponding image. Display 120 may be any type of display. For example, in some embodiments, display 120 may be a projector such as a panel-based (e.g., LCOS, DLP) projector or a scanning projector. Further, in some embodiments, display 120 may be a non-projection display such as an LED or AMOLED display.

Sampling clock generator 140 receives a sync signal on node 103 and a phase value on node 131, and generates the sampling clock provided to A/D 110 on node 141. Sampling clock generator 140 may receive other signals or data that are omitted from FIG. 1 for clarity. For example, sampling clock generator may receive a value sometimes referred to in the industry as HTOTAL, which corresponds to the number of clock transitions in a horizontal line of video. Also for example, the sync signal received on node 103 may correspond to a horizontal sync signal, a vertical sync signal, or both. Utilizing the information provided, sampling clock generator 140 determines the frequency of the sampling clock. For example, the sampling clock frequency may be determined as the product of HTOTAL and the frequency of horizontal sync.

The phase to be used for the sampling clock is provided by sampling phase determination component 130. In operation, sampling phase determination component 130 compares the difference between successive pixel values on node 111 to a threshold. This is performed for a plurality of different phase values. The result is a “phase profile” that characterizes system behavior as the number of times the threshold is exceeded as a function of sampling phase. A first phase is identified that corresponds to a minimum number of times the threshold is exceeded, and the sampling phase is chosen as a phase different from the first phase. In some embodiments, the sampling phase may be chosen as 180 degrees from the first phase, and in other embodiments, the sampling phase is chosen as either leading or lagging the first phase by 90 degrees.

In some embodiments, the threshold is adaptive. For example, once a phase profile is collected, the threshold may be increased or decreased based on characteristics of the phase profile. This may be iteratively performed for a fixed number of iterations or until one or more criteria are satisfied. Various apparatus and methods for adaptive threshold generation are described in further detail below.

Sampling phase determination component 130 may include any type of circuitry. For example, in some embodiments, sampling phase determination component 130 includes dedicated digital hardware to take successive differences of pixels, compare the differences to the threshold, produce the phase profile, and select a sampling phase. This dedicated digital hardware may take any form, including an application specific integrated circuit (ASIC), a field programmable gate array (FPGA), discrete components, or any combination. Also for example, in some embodiments, sampling phase determination component 130 may include a processor that executes program instructions to determine the sampling phase. In still further embodiments, sampling phase determination component 130 includes a combination of digital hardware and a processor to determine the sampling phase.

FIG. 2 shows a video signal and possible sampling clocks with different phases. Video signal 202 shows the pathological case in which each pixel takes on either the minimum analog value to the maximum analog value. During normal operation of a video display, video signal 202 would take on intermediate values corresponding to various grayscale pixel values; however, minimum and maximum values are shown in FIG. 2 to provide a simple example.

The vertical dashed lines correspond to the time at the center of the stable pixel value. One stable pixel value exists on node 111 (FIG. 1) for each vertical dashed line in FIG. 2. The analog-to-digital converter samples the analog video on the rising edge of the sampling clock.

Four possible phases for a sampling clock are shown at PHASE A, PHASE B, PHASE C, and PHASE D. These four phases are separated by substantially 90 degrees. Although four phases are shown in FIG. 2, the various embodiments of the present invention are not limited to four possible phase values. Some embodiments may choose between 8, 16, 32, 64, or more, different phase values. As can be seen in FIG. 2, PHASE A samples the analog video in the middle of the transition between pixels. This is a poor choice for the sampling phase because pixel values are not stable. A blurry or distorted image will result if PHASE A is chosen to sample the analog video signal.

Some embodiments of the present invention identify PHASE A as the first phase, and then select a phase different than PHASE A to sample the analog video. For example, in some embodiments, PHASE C is chosen to sample the analog video because it is 180 degrees from PHASE A. Also for example, in some embodiments, PHASE D is chosen as lagging 90 degrees behind PHASE C because this allows more time for the pixel value to settle on node 111 before sampling.

As described in more detail below, PHASE A is determined to be a poor choice for the sampling phase by comparing the difference of successive pixels to a threshold and finding PHASE A as the phase that produced the minimum number of threshold crossings. A sampling phase is then chosen as a phase other than PHASE A.

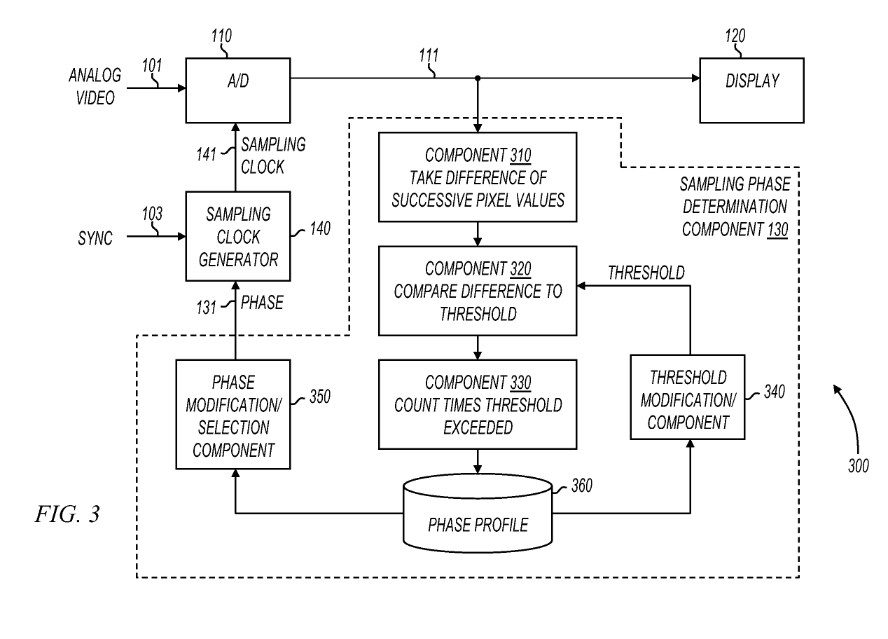

FIG. 3 shows a video system with a sampling phase determination component in accordance with various embodiments of the present invention. Video system 300 includes A/D converter 110, display 120, and sampling clock generator 140, all of which are described above with reference to FIG. 1. System 300 also includes sampling phase determination component 130. Various embodiments of components within sampling phase determination component 130 are shown in FIG. 3.

As shown in FIG. 3, sampling phase determination component 130 includes component 310 which takes differences of successive pixel values that appear on node 111. Component 320 compares the differences to a threshold, and component 330 counts the number of times the threshold is exceeded. Components 310, 320, and 330 may be implemented in any combination of hardware and software. For example, a first portion of components 310, 320, and 330 may be implemented in digital hardware, and a second portion may be implemented as program instructions that are executed by a processor.

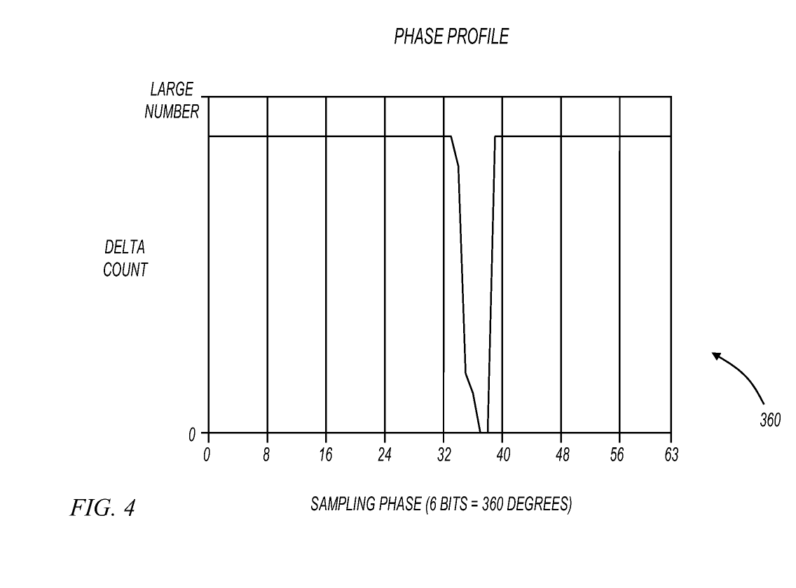

Phase modification/selection component 350 modifies the phase value provided to sampling clock generator 140. In some embodiments, phase modification/selection component 350 steps through various phase values, and components 310, 320, and 330 perform their respective actions for each phase value. This results in phase profile 360. Phase profile 360 includes data that shows the number of times the threshold is exceeded for each phase value. An example phase profile is shown in FIG. 4.

Threshold modification component 340 modifies the threshold used by component 320 in response to phase profile 360. For example, if phase profile 360 is flat, meaning that the number times the threshold is exceeded is substantially constant for every phase value, then threshold modification component 340 may increase or decrease the threshold, and another phase profile is then generated using the new threshold value.

Once a satisfactory threshold is determined, a final phase profile 360 is generated, and phase modification/selection component 350 selects a phase to be used during operation of system 300.

Phase modification/selection component 350 and threshold modification component 340 may be implemented in any manner without departing from the scope of the present invention. For example, these components may be implemented in any combination of hardware and/or software.

FIG. 4 shows a phase profile in accordance with various embodiments of the present invention. Phase profile 360 includes a “delta count” (the number of times the threshold is exceeded) for a number of different phase values. In the example of FIG. 4, the phase profile 360 includes delta count data for 64 phase values, corresponding to a six bit phase value representing 360 degrees of clock phase.

In some embodiments, phase modification/selection component 350 steps through 64 different phase values as phase profile 360 is generated. In other embodiments, the phase profile is generated by stepping through fewer than 64 phase values. For example, in some embodiments, phase modification/selection component 350 steps through every fourth six-bit phase value to yield a phase profile with 16 phase entries. Also for example, in some embodiments, the phase value is represented by more or fewer than six bits.

As shown in the example phase profile of FIG. 4, a minimum delta count is found at a phase value of approximately 38. In some embodiments, a sampling phase is selected 180 degrees from the phase with the minimum delta count. This yields a phase value of 6. In other embodiments, a sampling phase that leads by 90 degrees the minimum delta count phase. This yields a phase value of 22. Any phase value other than the minimum delta count phase may be chosen as the sampling phase without departing from the scope of the present invention.

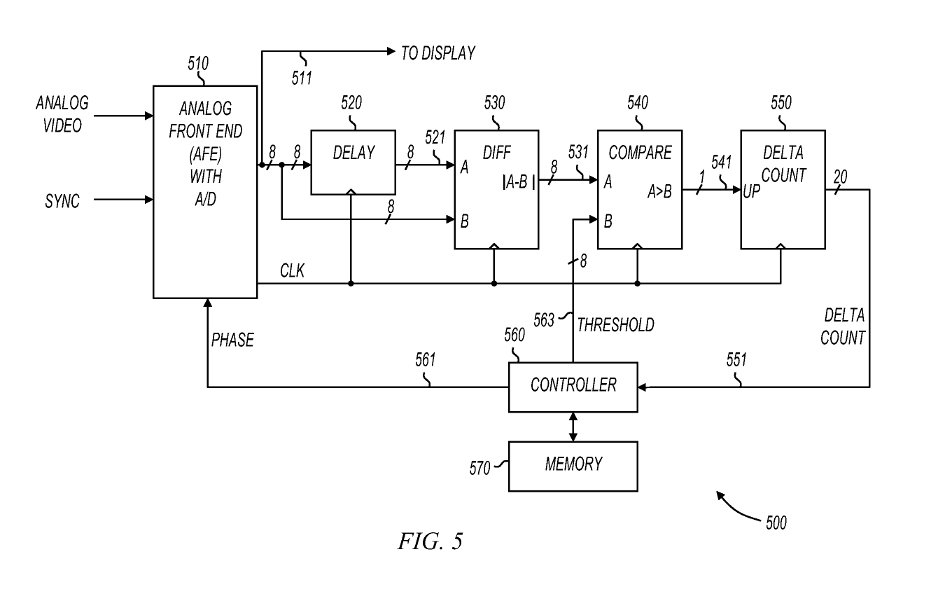

FIG. 5 shows a monochrome video system with a sampling phase determination component in accordance with various embodiments of the present invention. System 500 includes analog front end (AFE) 510, delay circuit 520, difference circuit 530, compare circuit 540, delta counter 550, controller 560, and memory 570.

AFE 510 receives an analog video signal, a sync signal, and a phase value, and produces digital pixel values and a clock signal. AFE 510 includes an analog-to-digital converter and an equivalent to sampling clock generator 140.

In operation, AFE 510 produces an internal sampling clock with a sampling phase corresponding to the phase value provided on node 561. AFE 510 then samples the analog video signal and produces a digital pixel value on node 511. Node 511 is shown as eight bits wide; however the various embodiments of the invention are not so limited. A/D resolution and pixel values may include any number of bits. Delay circuit 520 delays the pixel value on node 511 by one clock period. Delay circuit 520 may be any synchronous element capable of providing the desired pixel delay.

Difference circuit 530 receives successive pixel values on nodes 511 and 521. Difference circuit 530 takes the absolute value of the difference between the successive pixel values, and provides it on node 531. Difference circuit 530 may be any type of circuit capable of producing a difference of the two values. For example, difference circuit 530 may be a digital subtractor circuit.

Compare circuit 540 compares the difference of successive pixel values on node 531 with a threshold provided by controller 560 on node 563. When the difference of successive pixel values exceeds the threshold, a signal on node 541 is asserted to cause delta counter 550 to count up. Each time the signal on node 541 is asserted, the delta count value on node 551 is increased by one.

At the end of each video frame, controller 560 receives the delta count on node 551, provides the threshold value on node 563, the phase value on node 561 and resets the delta count 550. Controller 560 may be implemented using any suitable sequential circuits. For example, controller 560 may be implemented as a state machine in an ASIC, or may be implemented as a processor that executes instructions from memory 570. Controller 560 may be responsive to signals not shown in FIG. 5, and may also provide signals not shown in FIG. 5 to effect operations. For example, in some embodiments, controller 560 may provide reset signals to the various circuits shown in FIG. 5 to control when and how the various circuits are reset.

Although the delta count, the threshold, and the phase value are shown on separate nodes, this is not necessary a limitation of the present invention. For example, in some embodiments, controller 560 is a processor that communicates with the various circuits using a common bus. In these embodiments, the delta count, the threshold, and the phase value may be held in registers that are addressable by the controller.

Memory 570 may be any type of memory device. For example, in some embodiments, memory 570 represents a computer readable medium that can hold or be encoded with instructions. In these embodiments, controller 560 reads the instructions and performs actions in response thereto. Further, memory 570 may be used to store one or more phase profiles along with other data useful to execute computer programs. Examples of memory types suitable for use as memory 570 include random access memory (RAM), and nonvolatile re-writeable memory such as FLASH memory.

In operation, controller 560 sets a phase value on node 561, resets delta counter 550, and collects a delta count for the phase value over a number of successive pixels. In some embodiments, the delta count for the phase value is collected for one frame of video. Controller 560 then steps through a progression of phase values to collect a complete phase profile. Once a phase profile is collected, controller 560 may adaptively modify the threshold and/or select a sampling phase for continued operation of system 500. For example, in some embodiments, the threshold is modified in response to the phase profile, and another phase profile is collected. Once the phase profile satisfies one or more criteria, then a final threshold is set and a final phase profile is collected. Controller 560 then selects a sampling phase to be used for continued operation.

System 500 has been referred to as a monochrome system; however this is not a limitation of the present invention. For example, the system of FIG. 5 may be used in a color system, where only one color is used for sampling phase determination. In these embodiments, the analog video in FIG. 5 may correspond to one color (e.g., red) in a system with three color analog video (e.g., red, green, blue). In these embodiments, the successive pixels are of the single color, and the sampling phase is determined using the single color data. The resulting sampling phase may be used only for the color from which it was derived, or may be used for all colors in the system.

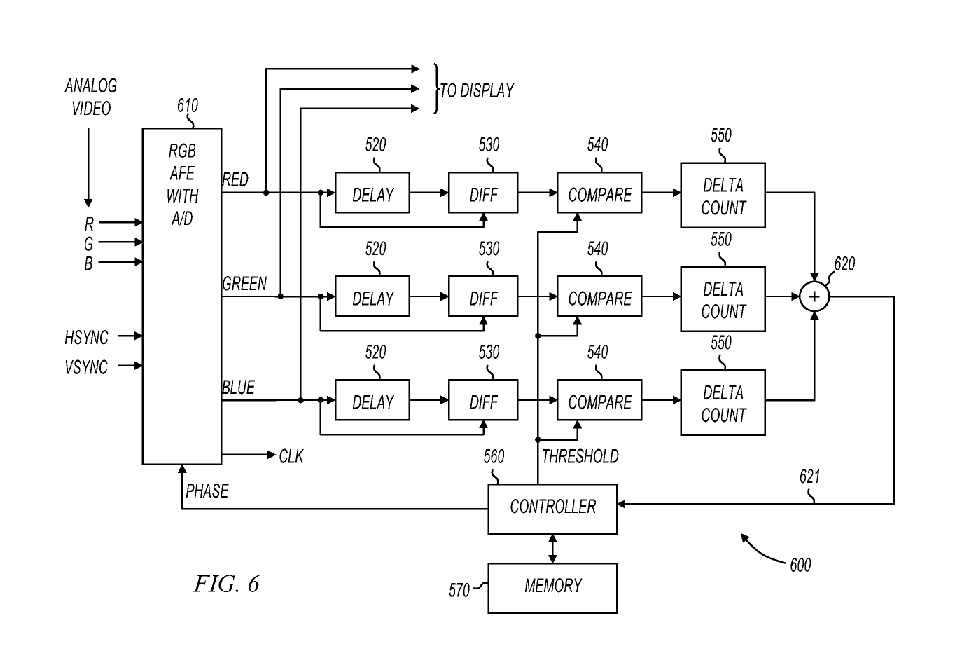

FIG. 6 shows a color video system with a sampling phase determination component in accordance with various embodiments of the present invention. System 600 includes a red-green-blue analog front end (RGB AFE) 610. RGB AFE 610 includes three analog-to-digital converters, one for each of red, green, and blue analog video signals. RGB AFE 610 also includes an equivalent of sampling clock generator 140. Circuits that perform the functions of RGB AFE are commercially available. One example is the ISL 98002 from Intersil Corporation of Milpitas, Calif.

System 600 also includes three delay circuits 520, three difference circuits 530, three compare circuits 540, and three delta counters 550. In operation, RBG AFE 610 digitizes three separate color channels, one each for red, green, and blue. The red, green, and blue pixel values are then operated on independently in the same manner as shown in FIG. 5. That is, differences of successive pixel values are compared to a threshold for each color, and delta counts are maintained for each color. Summing circuit 620 sums the individual delta counts and provides a sum of delta counts to controller 560 on node 621. Controller 560 could also read the delta counters separately for each color and sum them itself.

Phase profiles collected by system 600 include delta count sums for each phase value. Controller 560 operates as described above with reference to FIG. 5. The threshold may be adaptively modified based on collected phase profiles, and the phase value may be selected based on phase profiles.

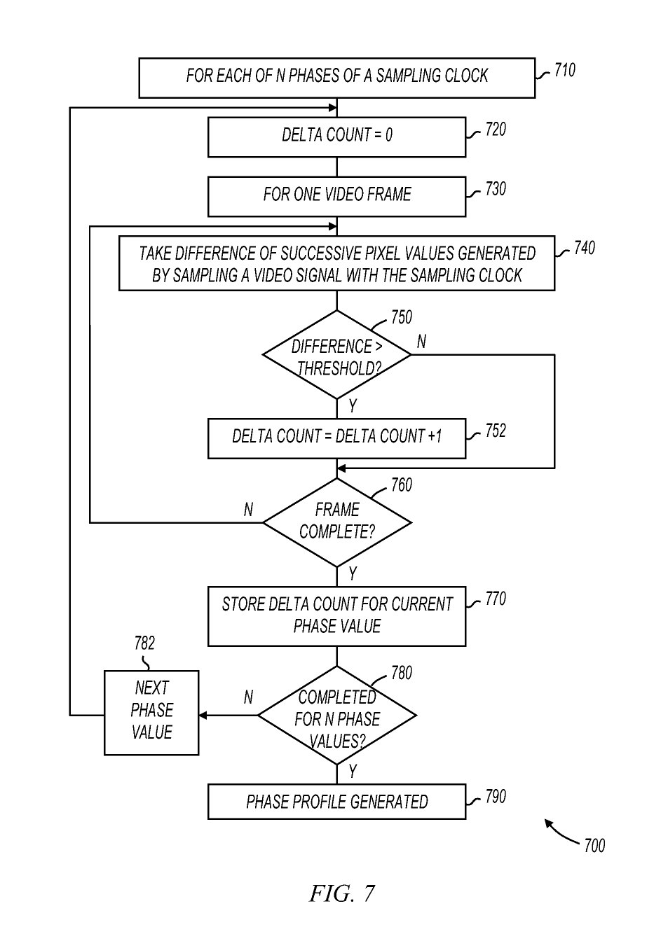

FIG. 7 shows a flowchart of a method for generating a phase profile in accordance with various embodiments of the present invention. In some embodiments, method 700, or portions thereof, is performed by a video system, embodiments of which are shown in previous figures. In other embodiments, method 700 is performed by a series of circuits, or a processor that executes instructions, or a combination of the two. Method 700 is not limited by the particular type of apparatus performing the method. The various actions in method 700 may be performed in the order presented, or may be performed in a different order. Further, in some embodiments, some actions listed in FIG. 7 are omitted from method 700.

Method 700 is shown beginning with block 710. Block 710 specifies that the actions in a number of following blocks are performed for N phase values of a sampling clock. This corresponds to phase modification/selection component 350 (FIG. 3) stepping through phase values, or controller 560 (FIGS. 5, 6) stepping through phase values. At 720, the delta count is reset to zero. This corresponds to resetting component 330 (FIG. 3) or delta counters 550 (FIGS. 5, 6).

Block 730 specifies that the actions in a number of following blocks are performed for one video frame. At 740, differences are taken of successive pixel values generated by sampling a video signal with the sampling clock. This corresponds to the operation of components 310 (FIG. 3), or delay and difference circuits 520 and 530 (FIGS. 5, 6). At 750, the difference is compared to the threshold. If the difference is greater than the threshold, then the delta count is incremented at 752. If the difference is not greater than the threshold, then the delta count remains the same. This corresponds to the operation of compare circuits 540 and delta counters 550 (FIGS. 5, 6).

At 760, a determination is made whether the frame is complete. This may be performed in any manner, including detecting a vertical sync signal. If the frame is not complete, then the actions in blocks 740, 750, and 752 are repeated. If the frame is complete, then the delta count for the current phase value is stored at 770. In some embodiments, delta counts for multiple color channels are summed. For example, summer 620 (FIG. 6) may sum the delta count, and the delta count sum for the current phase value may be stored.

The actions of blocks 730, 740, 750, 752, and 760 count how many times the threshold is exceeded over one frame's worth of pixels. In some embodiments, these blocks count how many times the threshold is exceeded over less than one frame or over more than one frame. For example, in some embodiments, each stored delta count value may correspond to less than one frame's worth of pixels. Also for example, in some embodiments, each stored delta count value may correspond to more than one frame's worth of pixels.

At the completion of the actions of block 770, one tuple of (phase value, delta count) or (phase value, delta count sum) is stored. This corresponds to one data value in phase profile 360 (FIG. 3, 4). At 780, a determination is made whether the process has been completed for all N phase values. If not, the next phase value is set at 782, and the method continues at 720. Setting the next phase value corresponds to phase modification/selection component 350 (FIG. 3) changing the phase value on node 131, or controller 560 changing the phase value on node 561 (FIGS. 5, 6). If the process has been completed for all N phase values, the phase profile has been generated as shown at 790.

Through the operation of method 700, N tuples of (phase value, delta count) or (phase value, delta count sum) have been stored, and together they make up a complete phase profile such as phase profile 360 (FIG. 3, 4). As described above, N may be every possible phase value, or may be a subset of every possible phase value. If the phase value is specified using six bits (as it is for the ISL 98002 part), N may be any value between two and 64. Using a large number of phase values provides more tuples for the phase profile, whereas using a smaller number of phase values allows the phase profile to be generated faster.

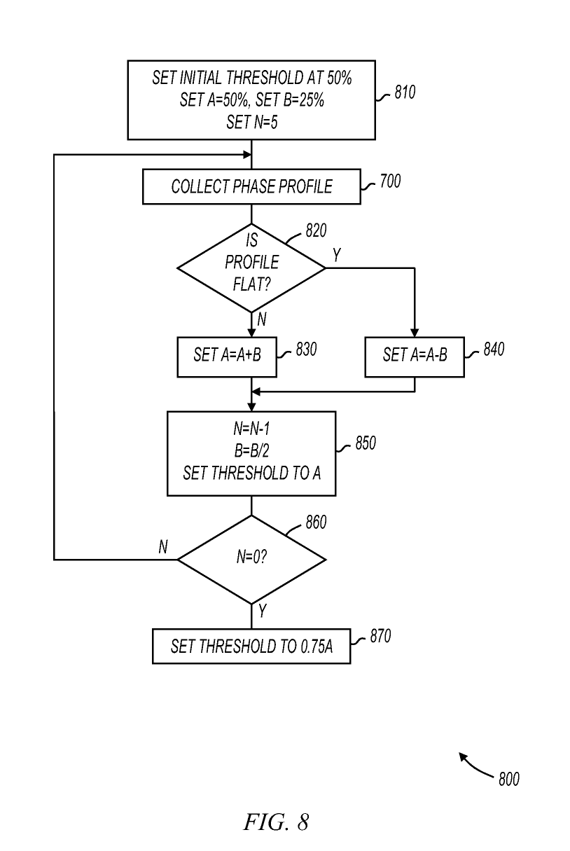

FIG. 8 shows a flowchart of a method for dynamically determining a threshold in accordance with various embodiments of the present invention. In some embodiments, method 800, or portions thereof, is performed by a video system, embodiments of which are shown in previous figures. In other embodiments, method 800 is performed by a series of circuits, or a processor that executes instructions, or a combination of the two. For example, method 800 may be performed by sampling phase determination component 130 (FIG. 1), threshold modification component 340 (FIG. 3), or controller 560 (FIGS. 5, 6). Method 800 is not limited by the particular type of apparatus performing the method. The various actions in method 800 may be performed in the order presented, or may be performed in a different order. Further, in some embodiments, some actions listed in FIG. 8 are omitted from method 800.

Method 800 is shown beginning with block 810 in which the threshold is initialized. The threshold may be initialized to any value. The example shown in FIG. 8 initializes the threshold at 50% of the peak-to-peak values of the analog video signal. For example, if the digitized video signal varies over 256 levels, then the threshold may be initialized to 128. Two local variables are also initialized. Variable N is initialized to 5, variable A is initialized to 50% and variable B is initialized to 25%.

At 700, a phase profile is collected as described above with reference to FIG. 7. At 820, a determination is made whether the phase profile is flat. A flat phase profile corresponds to a phase profile such as phase profile 360 (FIG. 4) without the dip in delta count values at phase values of 33-39. If the phase profile is flat, then A is reduced by the value of B at 840. If the phase profile is not flat, then A is increased by the value of B at 830.

At 850, N is decremented, B is halved, and the threshold is set to A. If at 860, N is not equal to zero, then another iteration is performed starting at block 700. The portion of method 800 thus far described implements a binary search algorithm for the threshold value that produces a nearly flat phase profile. Some embodiments use different adaptive algorithms for determining the threshold. Any algorithm may be used to determine the threshold without departing from the scope of the present invention.

At 870, the final threshold is set to a value less than the threshold arrived at by the binary search. As an example, the threshold is set at 0.75A. Selecting a threshold less than the value determined in the binary search assures that the resulting phase profile will have a pronounced dip so that the phase with the minimum delta count may be found.

The threshold found by method 800 will be dependent on the contrast of the incoming video image. High contrast images have larger differences between successive pixels. The desired threshold is also dependent on the rate that video changes with time (e.g., the frequency content). For example, images containing text have relatively high frequency content which will result in larger differences between successive pixels.

In the operation of method 800, if the video is low in contrast, as in dim video, the initial phase profile will be all zeros as the video content will never change enough to exceed the threshold. In this case, the threshold is adjusted down. Otherwise, the threshold is adjusted upward. In either case, a new phase profile is collected and the process repeats until a suitable threshold is found.

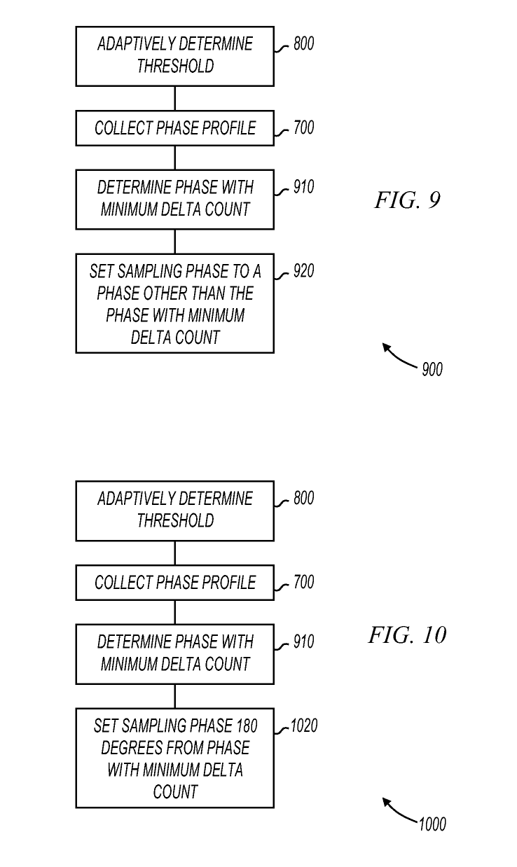

FIGS. 9 and 10 show flowcharts of methods for determining a sampling phase in accordance with various embodiments of the present invention. In some embodiments, methods 900 and 1000, or portions thereof, are performed by a video system, embodiments of which are shown in previous figures. In other embodiments, methods 900 and 1000 are performed by a series of circuits, or a processor that executes instructions, or a combination of the two. For example, methods 900 and 1000 may be performed by sampling phase determination component 130 (FIG. 1), phase modification/selection component 350 (FIG. 3), or controller 560 (FIGS. 5, 6). Methods 900 and 1000 are not limited by the particular type of apparatus performing the method. The various actions in methods 900 and 1000 may be performed in the order presented, or may be performed in a different order. Further, in some embodiments, some actions listed in FIGS. 9 and 10 are omitted from methods 900 and 1000.

Method 900 begins at block 800 in which the threshold is adaptively determined as described above with reference to FIG. 8. Once the threshold is set, a phase profile is collected at 700 as described above with reference to FIG. 7. At 910, the phase value with the minimum delta count is found, and at 920, the sampling phase is set to a phase other than the phase value with the minimum delta count.

Method 1000 begins at block 800 in which the threshold is adaptively determined as described above with reference to FIG. 8. Once the threshold is set, a phase profile is collected at 700 as described above with reference to FIG. 7. At 910, the phase value with the minimum delta count is found, and at 1020, the sampling phase is set to a phase 180 degrees from the phase value with the minimum delta count.

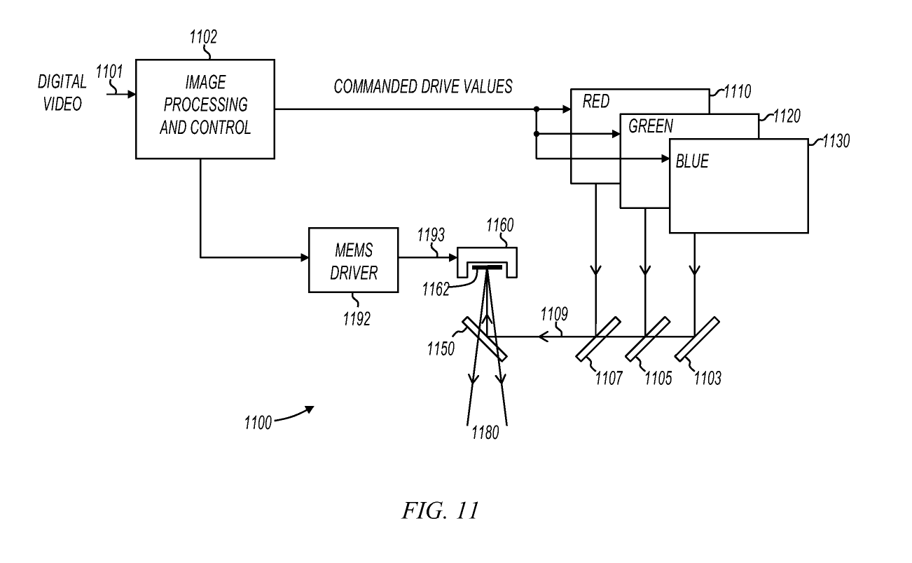

FIG. 11 shows a color laser projection apparatus. Laser projection apparatus is an example display that may be included in a video system as display 120 (FIGS. 1, 3). Apparatus 1100 includes image processing and control component 1102 and laser light sources 1110, 1120, and 1130. Apparatus 1100 also includes mirrors 1103, 1105, and 1107, fold mirror 1150, micro-electronic machine (MEMS) device 1160 having mirror 1162, and MEMS driver 1192.

In operation, image processing and control component 1102 receives video data on node 1101. This video data corresponds to the pixel data on node 111 (FIGS. 1, 2). Image processing and control component produces commanded drive values to drive the laser light sources when pixels are to be displayed. Image processing and control component 1102 may include any suitable hardware and/or software useful to produce commanded drive values from video data. For example, image processing and control component 1102 may include application specific integrated circuits (ASICs), one or more processors, or the like.

Laser light sources 1110, 1120, and 1130 receive commanded drive values and produce light. Each light source produces a narrow beam of light which is directed to the MEMS mirror via guiding optics. For example, blue laser light source 1130 produces blue light which is reflected off mirror 1103 and is passed through mirrors 1105 and 1107; green laser light source 1120 produces green light which is reflected off mirror 1105 and is passed through mirror 1107; and red laser light source 1110 produces red light which is reflected off mirror 1107. At 1109, the red, green, and blue light are combined. The combined laser light is reflected off mirror 1150 on its way to MEMS mirror 1162. The MEMS mirror rotates on two axes in response to electrical stimuli received on node 1193 from MEMS driver 1192. After reflecting off MEMS mirror 1162, the laser light bypasses mirror 1150 to create an image at 1180. The MEMS based projector is described as an example display apparatus, and the various embodiments of the invention are not so limited. For example, the sampling phase determination apparatus and methods described herein may be used with other display systems without departing from the scope of the present invention.

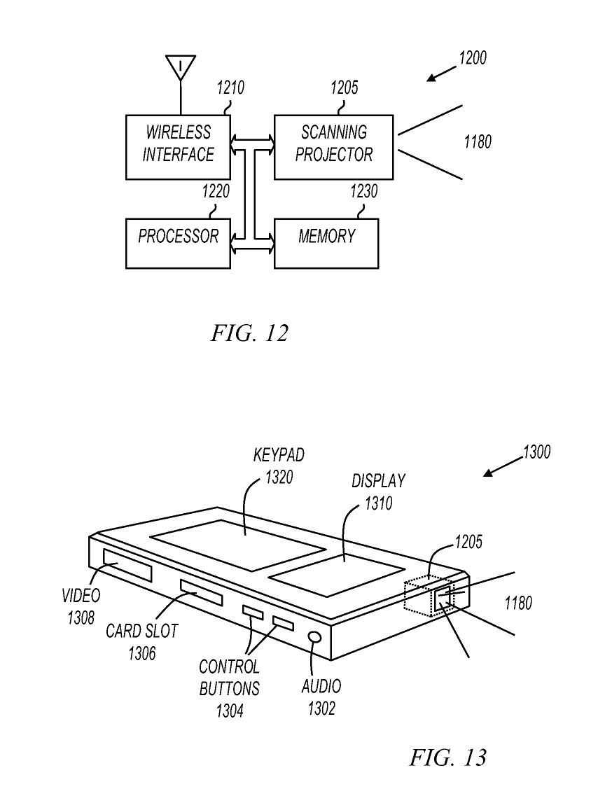

FIG. 12 shows a block diagram of a mobile device in accordance with various embodiments of the present invention. As shown in FIG. 12, mobile device 1200 includes wireless interface 1210, processor 1220, memory 1230, and scanning projector 1205. Scanning projector 1205 corresponds to video system 100 (FIG. 1) in which the display 120 is implemented as apparatus 1100 (FIG. 11). Scanning projector 1205 paints a raster image at 1180. In some embodiments, scanning projector 1205 includes one or more sampling phase determination components, such as those shown in, and described with reference to, earlier figures.

Scanning projector 1205 may receive image data from any image source. For example, in some embodiments, scanning projector 1205 includes memory that holds still images. In other embodiments, scanning projector 1205 includes memory that includes video images. In still further embodiments, scanning projector 1205 displays imagery received from external sources such as connectors, wireless interface 1210, or the like.

Wireless interface 1210 may include any wireless transmission and/or reception capabilities. For example, in some embodiments, wireless interface 1210 includes a network interface card (NIC) capable of communicating over a wireless network. Also for example, in some embodiments, wireless interface 1210 may include cellular telephone capabilities. In still further embodiments, wireless interface 1210 may include a global positioning system (GPS) receiver. One skilled in the art will understand that wireless interface 1210 may include any type of wireless communications capability without departing from the scope of the present invention.

Processor 1220 may be any type of processor capable of communicating with the various components in mobile device 1200. For example, processor 1220 may be an embedded processor available from application specific integrated circuit (ASIC) vendors, or may be a commercially available microprocessor. In some embodiments, processor 1220 provides image or video data to scanning projector 1205. The image or video data may be retrieved from wireless interface 1210 or may be derived from data retrieved from wireless interface 1210. For example, through processor 1220, scanning projector 1205 may display images or video received directly from wireless interface 1210. Also for example, processor 1220 may provide overlays to add to images and/or video received from wireless interface 1210, or may alter stored imagery based on data received from wireless interface 1210 (e.g., modifying a map display in GPS embodiments in which wireless interface 1210 provides location coordinates).

FIG. 13 shows a mobile device in accordance with various embodiments of the present invention. Mobile device 1300 may be a hand held projection device with or without communications ability. For example, in some embodiments, mobile device 1300 may be a handheld projector with little or no other capabilities. Also for example, in some embodiments, mobile device 1300 may be a device usable for communications, including for example, a cellular phone, a smart phone, a personal digital assistant (PDA), a global positioning system (GPS) receiver, or the like. Further, mobile device 1300 may be connected to a larger network via a wireless (e.g., WiMax) or cellular connection, or this device can accept data messages or video content via an unregulated spectrum (e.g., WiFi) connection.

Mobile device 1300 includes scanning projector 1205 to create an image with light at 1180. Mobile device 1300 also includes many other types of circuitry; however, they are intentionally omitted from FIG. 13 for clarity.

Mobile device 1300 includes display 1310, keypad 1320, audio port 1302, control buttons 1304, card slot 1306, and audio/video (A/V) port 1308. None of these elements are essential. For example, mobile device 1300 may only include scanning projector 1205 without any of display 1310, keypad 1320, audio port 1302, control buttons 1304, card slot 1306, or A/V port 1308. Some embodiments include a subset of these elements. For example, an accessory projector product may include scanning projector 1205, control buttons 1304 and A/V port 1308.

Display 1310 may be any type of display. For example, in some embodiments, display 1310 includes a liquid crystal display (LCD) screen. Display 1310 may always display the same content projected at 1180 or different content. For example, an accessory projector product may always display the same content, whereas a mobile phone embodiment may project one type of content at 1180 while display different content on display 1310. Keypad 1320 may be a phone keypad or any other type of keypad.

A/V port 1308 accepts and/or transmits video and/or audio signals. For example, A/V port 1308 may be a digital port that accepts a cable suitable to carry digital audio and video data. Further, A/V port 1308 may include RCA jacks to accept composite inputs. Still further, A/V port 1308 may include a VGA connector to accept analog video signals. In some embodiments, mobile device 1300 may be tethered to an external signal source through A/V port 1308, and mobile device 1300 may project content accepted through A/V port 1308. In other embodiments, mobile device 1300 may be an originator of content, and A/V port 1308 is used to transmit content to a different device.

Audio port 1302 provides audio signals. For example, in some embodiments, mobile device 1300 is a media player that can store and play audio and video. In these embodiments, the video may be projected at 1180 and the audio may be output at audio port 1302. In other embodiments, mobile device 1300 may be an accessory projector that receives audio and video at A/V port 1308. In these embodiments, mobile device 1300 may project the video content at 1180, and output the audio content at audio port 1302.

Mobile device 1300 also includes card slot 1306. In some embodiments, a memory card inserted in card slot 1306 may provide a source for audio to be output at audio port 1302 and/or video data to be projected at 1180. Card slot 1306 may receive any type of solid state memory device, including for example, Multimedia Memory Cards (MMCs), Memory Stick DUOS, secure digital (SD) memory cards, and Smart Media cards. The foregoing list is meant to be exemplary, and not exhaustive.

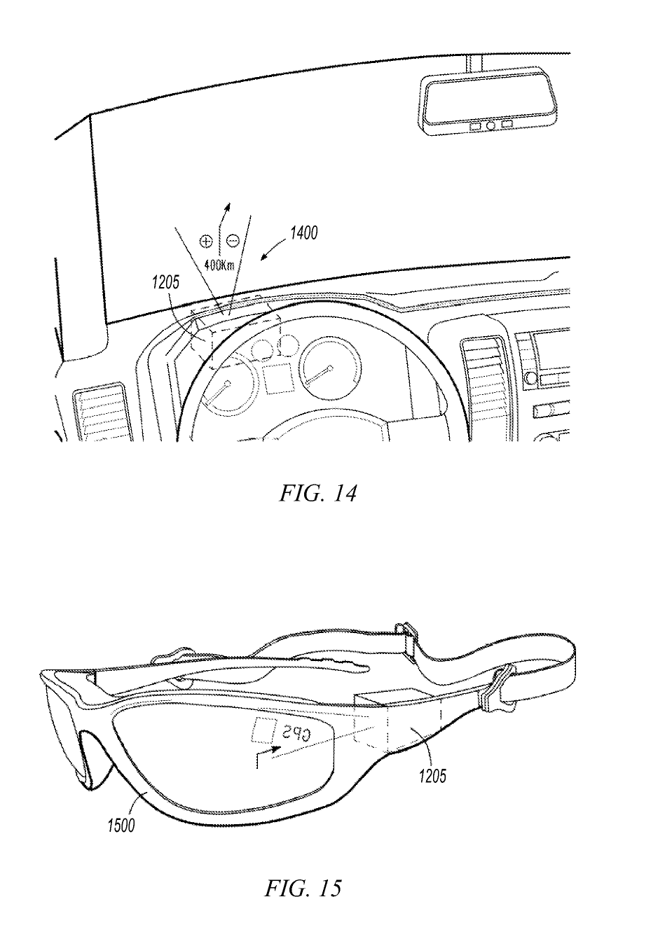

FIG. 14 shows a head-up display system in accordance with various embodiments of the invention. Projector 1205 is shown mounted in a vehicle dash to project the head-up display at 1400. Although an automotive head-up display is shown in FIG. 14, this is not a limitation of the present invention. For example, various embodiments of the invention include head-up displays in avionics application, air traffic control applications, and other applications.

FIG. 15 shows eyewear in accordance with various embodiments of the invention. Eyewear 1500 includes projector 1205 to project a display in the eyewear's field of view. In some embodiments, eyewear 1500 is see-through and in other embodiments, eyewear 1500 is opaque. For example, eyewear 1500 may be used in an augmented reality application in which a wearer can see the display from projector 1205 overlaid on the physical world. Also for example, eyewear 1500 may be used in a virtual reality application, in which a wearer's entire view is generated by projector 1205. Although only one projector 1205 is shown in FIG. 15, this is not a limitation of the present invention. For example, in some embodiments, eyewear 1500 includes two projectors; one for each eye.

Although the present invention has been described in conjunction with certain embodiments, it is to be understood that modifications and variations may be resorted to without departing from the scope of the invention as those skilled in the art readily understand. Such modifications and variations are considered to be within the scope of the invention and the appended claims.

What is claimed is:

1. A method comprising:
comparing differences of successive pixel values to a threshold for each of a plurality of phases of a sampling clock that is used to sample a video signal to generate the successive pixel values;
counting a number of times the threshold is exceeded at each of the plurality of phases to create a phase profile;
finding a first phase that corresponds to a minimum count in the phase profile; and
selecting a phase other than the first phase to sample the video signal.

2. The method of claim 1 wherein comparing differences of successive phase values to a threshold comprises comparing successive phase values of one color video stream to the threshold.

3. The method of claim 1 wherein comparing differences of successive phase values to a threshold comprises comparing successive pixel values of each of red, green, and blue video streams to the threshold.

4. The method of claim 3 wherein counting a number of times the threshold is exceeded comprises summing the number of times the threshold is exceeded in all of the red, green, and blue video streams.

5. The method of claim 1 wherein counting the number of times the threshold is exceeded comprises counting over one video frame for each of the plurality of phases.

6. The method of claim 1 wherein selecting a phase other than the first phase to sample the video signal comprises selecting a phase 180 degrees from the first phase.

7. A method comprising:
comparing differences of successive pixel values to a threshold for each of a plurality of phases of a sampling clock that is used to sample a video signal to generate the successive pixel values;
counting a number of times the threshold is exceeded at each of the plurality of phases to create a phase profile;
adaptively modifying the threshold based on the phase profile; and
selecting a phase from the plurality of phases to sample the video signal.

8. The method of claim 7 wherein adaptively modifying the threshold comprises performing a binary search for a threshold that yields a substantially flat phase profile.

9. The method of claim 8 further comprising setting the threshold to a value less than a threshold value determined in the binary search.

10. The method of claim 7 wherein adaptively modifying the threshold comprises iteratively modifying the threshold and collecting a phase profile.

11. An apparatus comprising:
an analog-to-digital converter to sample an analog video signal and to generate pixel values for each of a plurality of phase values of a sampling clock;
a first component to determine differences of successive pixel values;
a second component to compare the differences of successive pixel values to a threshold;
a third component to count the number of times the threshold is exceeded for each of the plurality of phases to create a phase profile;
a threshold modification component to modify the threshold in response to the phase profile; and
a phase selection component to select a sampling phase in response to the phase profile.

12. The apparatus of claim 11 further comprising a display.

13. The apparatus of claim 11 wherein the display comprises a scanning projector.

14. The apparatus of claim 11 wherein the analog video signal comprises red, green, and blue analog video signals.

15. The apparatus of claim 14 wherein the second component compares differences of successive pixel values for each of red, green, and blue to the threshold.

16. The apparatus of claim 15 wherein the third component counts and sums the number of times the threshold is exceeded for each of red, green, and blue.

17. An electronic system comprising:
a display device to accept pixel values and to display a corresponding image;
an analog-to-digital converter to accept an analog video signal and to generate the pixel values; and
a sampling clock phase determination component to determine a phase for a sampling clock to drive the analog-to-digital converter, the sampling clock phase determination component including a circuit to compare successive pixel values to a dynamic threshold.

18. The electronic system of claim 17 further comprising a wireless interface to receive video data.

19. The electronic system of claim 18 wherein the wireless interface comprises a cellular telephone interface.

20. The electronic system of claim 17 wherein the scanning projector is configured to operate as a head-up display.
